(19) United States
(12) Patent Application Publication
(10) Pub. No.: US 2016/0109802 A1
(43) Pub. Date: Apr. 21, 2016

(54) METHOD FOR PRINTING A DIGITAL IMAGE ON A STYLIZED METALLIC SHEET

(71) Applicant: Shinkle Fine Art, LLC, Bloomfield Hills, MI (US)

(72) Inventors: Theodore M. Shinkle, Bloomfield Hills, MI (US); Linda K. Shinkle Rodney, Bloomfield Hills, MI (US)

(21) Appl. No.: 14/979,874

(22) Filed: Dec. 28, 2015

Related U.S. Application Data
(63) Continuation of application No. 14/093,693, filed on Dec. 2, 2013.
(60) Provisional application No. 61/732,805, filed on Dec. 3, 2012.

(51) Int. Cl. G03F 7/16; B44C 1/00; F21V 33/00

(52) U.S. Cl. CPC G03F 7/16; F21V 33/0032; B44C 1/00; F21Y 2103/003

(57) ABSTRACT

A method for creating an artistic image involving printing a digital image on the front surface of a regionally stylized metallic sheet. The method includes the steps of preparing a preparatory image, selecting one or more regions of the front surface for stylization, placing the preparatory image on the front surface of the metallic sheet, stylizing the selected regions with techniques such as physical abrasion, chemical reaction, or heat, and then digitally printing the digital image upon the regionally stylized front surface of the metallic sheet to produce the artistic image. The invention also includes articles produced by this method.

### BACKGROUND OF THE INVENTION

Digital images and improved printer technology allow use of printing substrates other than photographic paper. For example, it is known to use an ink-jet printer to print images on a sheet of aluminum. It is also known to precoat the metallic sheet with certain commercially available products in order to promote adhesion of ink to the metal substrate. It is further known to apply acrylic- and/or urethane-based coatings to seal, protect and finish the aluminum sheet after the ink is applied. The image that results from digitally printing on a treated metal substrate has unique attractive qualities, which may include heightened luminosity. This attractive feature may be especially desirable for artwork.

However, current methods of printing an image on metal pose at least two problems to artists. First, although a few companies print on metal sheets using digital images supplied by others, the cost is high. More problematic, current metal-printing techniques limit artistic treatment of the metal sheet. Skilled artists currently operate under the well-accepted assumption that a uniform metal surface is desirable for best printing results. This limitation constrains artistic treatment of the underlying substrate thereby limiting resulting final appearance. Regardless of whether one out-sources the printing or the artist does it herself, current metal-printing techniques do not include selectively treating or stylizing regions of the metal prior to printing. Existing methods thus essentially confine the artist-photographer to printing an image on the homogeneous, unaltered, unstylized and untreated metal surfaces that are commercially available.

What is needed is a metal-printing method that allows artist-photographers to stylize and treat a metal sheet prior to printing a digital image, thereby enabling the artist to introduce textures and surface features in the metal.

### SUMMARY OF THE INVENTION

Disclosed is a method for creating an artistic image involving printing a digital image on the front surface of a metallic sheet. The method includes the steps of preparing a preparatory image having dimensions corresponding to the dimensions desired for the printed image, selecting one or more regions of the front surface for stylization, placing the preparatory image on the front surface of the metallic sheet, stylizing the selected regions according to a technique such as physical abrasion, chemical reaction, or heat, and then digitally printing the digital image upon the regionally stylized front surface of the metallic sheet to produce the artistic image. The invention also includes articles produced by this method.

### BRIEF DESCRIPTION OF THE DRAWINGS

These and other features and advantages of the present invention will become more readily appreciated when considered in connection with the following detailed description and appended drawings, wherein:

FIG. 1 is a depiction of a digital image.

FIG. 2 is a perspective view of the digital image being projected by a digital light projector onto a surface.

FIG. 3A is the digital image projected onto the front surface of a metallic sheet.

FIG. 3B is the front surface of the metallic sheet showing masking material covering selected regions of the sheet.

FIG. 3C is the masked metallic sheet showing how it can be regionally stylized or treated by techniques such as physical abrasion, chemical treatment, or heat.

FIG. 3D is the metallic sheet shown after the step of stylization/treatment and after the masking material is removed, showing regions of stylization/treatment.

FIG. 3E is the metallic sheet shown with the digital image imprinted on the regionally stylized metallic sheet.

FIG. 4 is a top view of the regionally stylized metallic sheet imprinted with the digital image placed on a flat and level base, with the base comprising three side portions each abutting a central portion.

FIG. 5 is a side view of the stylized metallic sheet placed on top of the base.

FIG. 6 is a top view of the metallic sheet shown abutted by matboard strips on three sides prepared for insertion into a printer.

FIG. 7 is a rear view of the finished artpiece showing a frame adhered to the metallic sheet and attached light source.

FIG. 7A is a side view of the finished artpiece showing the frame and attached light source.

### DETAILED DESCRIPTION OF THE INVENTION

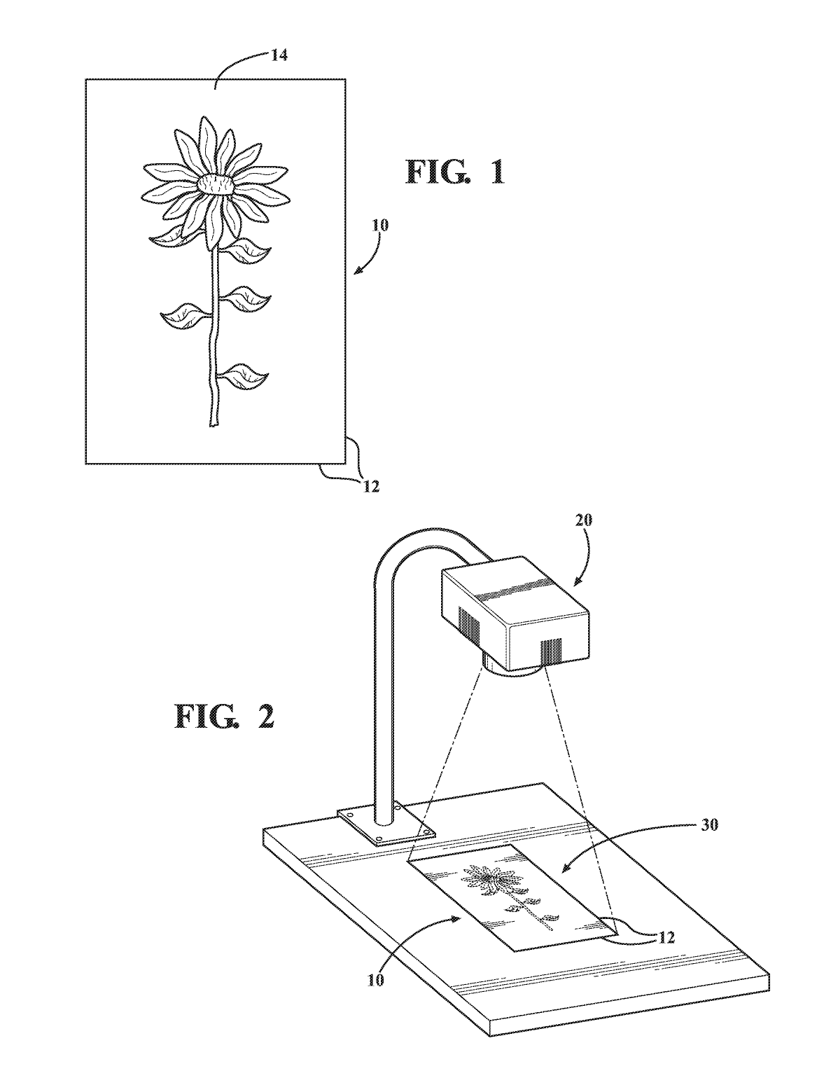

Before describing the invented method, it is useful to review FIGS. 1-3E. Referring to the figures, wherein like numerals indicate like or corresponding parts throughout the several views, FIG. 1 depicts a digital image 10 such as a digital photograph. The image is typically rectangular but can be any shape. For ease of explanation, FIG. 1 simply depicts a flower. Digital image 10 includes the entire image within digital image boundaries 12. Digital image boundaries 12 do not necessarily correspond to the original boundaries of the source image, such as a digital photograph; the original photograph (or other digital image) may have been cropped or otherwise manipulated to define digital image boundaries 12. Digital image 10 has a top 14. If an artpiece imprinted with digital image 10 is displayed on vertical wall, for example, the artpiece would be oriented so that top 14 is at the top of the artpiece.

FIG. 2 depicts a light projector 20 projecting digital image 10 on a flat surface. Metallic sheet 30 is shown lying on the flat surface. FIG. 2 shows the flower within digital image 10 in dashed lines to indicate that the image is produced by light projection. Digital image boundaries 12 projected by light projector 20 preferably correspond to the dimensions and orientation of a desired final artistic image.

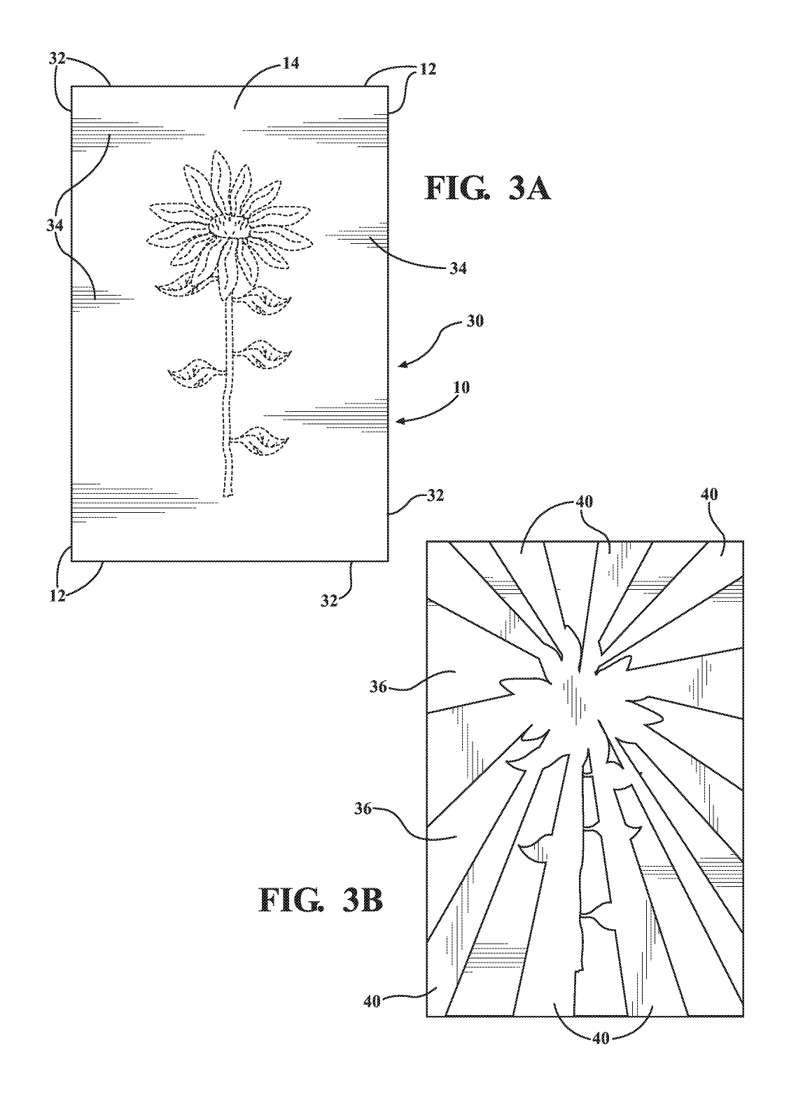

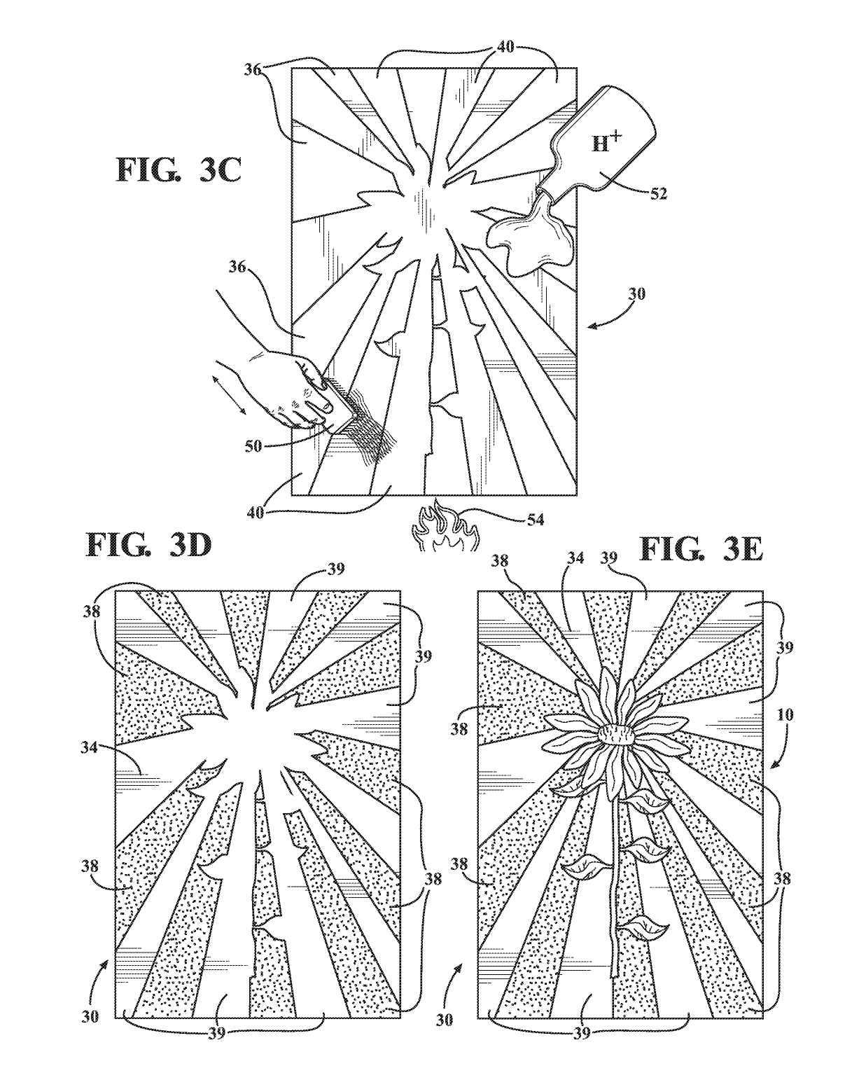

FIG. 3A shows digital image 10 projected onto a metallic sheet 30. Metallic sheet 30 is shown as rectangular but can be any shape. Metallic sheet 30 can be aluminum, stainless steel, silver, gold, or any substrate having a metal surface. Optionally, metallic sheet 30 can be a metallic or nonmetallic base substrate overlaid with a metal, such as an aluminum base electrocoated with gold or silver. Metallic sheet 30 is formed by cutting metal sheeting to desired metallic sheet dimensions 32. 0.025-gauge aluminum sheeting may be used, or other gauges including but not limited to 0.020 and 0.032 gauge. Good results have been obtained using aluminum sheeting of the alloy type 5052H32. When metallic sheet 30 is a homogenous metal such as mill run aluminum sheeting, the sheet typically has a grain or granular direction 34, depicted in FIG. 3 as horizontal “shimmer lines.” The grain of metallic sheet 30 will ordinarily run parallel to the mill run of the original rolled metal coil. FIGS. 3A-3E show granular direction 34 oriented horizontally relative to top 14 of digital image 10.

FIGS. 3B shows the front surface of metallic sheet 30 partially covered by a masking material 40. To assist in distinguishing elements shown in the drawings, FIGS. 3B and 3C show masking material 40 with vertical “shimmer lines” and the exposed front surface 36 of metallic sheet 30 with horizontal “shimmer lines” consistent with horizontal granular direction 34 of metallic sheet 30. FIG. 3B shows the region of the flower within digital image 10 as completely masked by masking material 40. The region of digital image 10 surrounding the flower is partially masked, with the masking material 40 placed in a burst pattern centered on the area of the flower blossom within digital image 10 and extending outward to digital image boundaries 12.

FIG. 3C is similar to FIG. 3B and additionally depicts a stylization or treatment step. For purposes of this specification and the claims, “stylize” means stylization and treatment of the front surface of the metallic sheet by a variety of techniques, including physical abrasion 50, chemical treatment 52, heat 54, and potentially other surface treatments such as exposure to electromagnetism or radiation. Physical abrasion may occur, for example, by applying to the exposed front surface 36 of metallic sheet 30 sandpaper, steel wool, wire brushes, files, grinding stones, power tools equipped with various abrasive attachments, etching and engraving tools, or striking the front surface with objects such as hammers or chains. Chemical treatment may include such things as acids, oxidants, salts, or other materials that react with metallic sheet 30. Heat treatment might be applied either generally or locally using for example a handheld propane torch, or heat treatment might involve heat removal using for example liquid nitrogen. As will be described, stylization can occur in one step, or in sequential steps, or in combination. For example, one might physically abrade a region using a first stylization technique, then in a second stylization technique physically abrade the same region again in the presence of a reactive chemical such as an acid, then stylize a different region with yet another technique. After any or all of the foregoing stylization and/or treatments, metallic sheet 30 may further treated by general exposure to heat, cold, sunshine, and water, with or without simultaneous exposure various corrosive elements described above to further treat the piece. Exposure to exterior elements can range from a few hours to six or more months. If the metallic sheet is exposed to high heat or extreme cold, the affected area is preferably stabilized, such as with a press or clamps, to minimize warping.

FIG. 3D shows metallic sheet 30 subsequent to one or more stylization steps and subsequent to removal of masking material 40 from metallic sheet 30. The exposed front surface regions 36 in FIG. 3C that were not masked are now stylized regions 38 and are depicted with irregular stippling to indicate stylization treatment. The regions that were formerly masked by masking material 40 in FIG. 3C are revealed in FIG. 3D as unstylized regions 39 having horizontal granular direction 34. In this example and for ease of description, FIGS. 3B-3E show the area of metallic sheet 30 that will bear the imprint of the flower as an unstylized region 39. It will be understood that in practice, the digital image 10 preferably extends to the boundaries 32 of the metallic sheet 30, and that significant stylization may occur anywhere on metallic sheet 30.

FIG. 3E shows a completed artistic image comprising the imprinted digital image 10 on metallic sheet 30. Subsequent to printing digital image 10, stylized regions 38 have a different surface texture and luminosity compared to unstylized regions 39. For simplicity, FIG. 3E depicts a metallic sheet following only one stylization technique on one set of stylized regions 38. It will be understood that stylization may occur in a plurality of steps or layers, with some stylization steps focused on certain regions and other stylization steps performed sequentially or in combination on a common set of regions.

A method of preparing an artpiece embodying the invention will now be described with reference to the figures. Metallic sheet 30 may be initially treated using corrosive and/or oxidizing chemicals 52 such as acid, vinegar, dish washing detergent, calcium chloride, sodium chloride. Metallic sheet 30 may also be treated at this stage with heat 54, such as open flame, kerosene, or liquid nitrogen. Metallic sheet 30 may be regionally masked at this step using common masking tape such as sold by 3M, so that initial treatment is confined to unmasked regions.

For a next step, and ordinarily after any initial treatment with chemicals or heat, metallic sheet 30 may be cleaned before further stylization is performed. However, it is not strictly necessary to clean metallic sheet 30 at this step if further stylization will occur. Metallic sheet 30 may be cleaned using commercially available compounds including degreasers. Although soaps, detergents or acetone may be used as cleaning agents, more preferable is a grease remover such as Professional Strength Goof Off, followed by a natural multi-purpose cleaner such as “Citrasolv,” and then finally 70% or greater percentage isopropyl alcohol.

Before proceeding to stylize the front surface of metallic sheet 30, a preparatory image is prepared to aid the artist in i) selecting areas to be stylized and ii) applying the chosen stylization technique to the selected areas. The preparatory image may be prepared in various ways. In a first embodiment, the preparatory image is a projected light image placed on a front surface of metallic sheet 30 using a digital light projector 20 to project digital image 10 upon metallic sheet 30, as shown in FIGS. 2 and 3A, such that the desired digital image boundaries 12 are substantially coequal with the metallic sheet dimensions 32. Using the preparatory image, the artist selects one or more regions on the front surface of metallic sheet 30 to stylize. In addition to facilitating precise targeting of stylistic treatment, use of a projector on different portions of the metallic sheet allows greater artistic flexibility and variety while promoting efficiency and low cost.

The artist may choose to stylize regions with the aid of masking materials, or may proceed directly to stylize the selected regions without masking. Using the flower depicted in the Figures, for example, the artist may select a region generally underneath the flower to stylize with physical abrasion, such as steel wool. In that example, the area of physical abrasion could be diffuse and not sharply defined.

Returning to the description of the first embodiment, it is contemplated that most artists will desire to more sharply define regions for stylization using a masking material 40. Using the preparatory image placed on metallic sheet 30 resulting from the projected digital image shown in FIGS. 2 and 3A, the artist applies a masking material to the regions of front surface of metallic sheet 30 that the artist does not want to stylize at this step. After the artist masks the areas not selected for stylization, the light projector 20 may be turned off thereby removing the preparatory image from the front surface of metallic sheet 30. As shown in FIG. 3B, the resulting metallic sheet 30 is partially masked with masking material 40, leaving regions of exposed front surface 36. The artist may then proceed to stylize the selected exposed regions 36 using an abrasion tool 50, chemical treatment 52, or heat treatment 54.

In a second embodiment, the preparatory image may be a mask comprising masking material 40. Returning to FIG. 2, instead of projecting digital image 20 onto metallic sheet 30 as shown, digital image 20 may be projected onto intact masking material 40. The boundaries of the projected digital image are substantially coequal with metallic sheet dimensions 32 and preferably correspond to the size and orientation of a desired final artistic image. Masking material 40 may be clear adhesive-backed film, or any material that will protect the front surface of the metallic sheet from the treatment technique contemplated, including cardboard, metal sheeting, or plastic. In this second embodiment, the artist prepares the preparatory image by consulting the projected digital image 10 as it appears on masking material 40, selecting one or more regions to stylize, and excising those selected regions from the masking material. In this embodiment, the mask that results from excision of the selected regions of masking material 40 is the preparatory image. The preparatory image is then securely placed on the front surface of metallic sheet 30, as shown in FIG. 3B. As in the embodiment discussed above, FIG. 3B shows exposed front surface regions 36 of metallic sheet 30 that are prepared for stylization, situated adjacent to regions not selected for stylization and masked by masking material 40.

In a third embodiment, the preparatory image may be prepared by printing digital image 10 directly on masking material 40, such as transparent adhesive film. The imprint of digital image 10 has boundaries 12 that are substantially coequal with metallic sheet dimensions 32 and preferably correspond to the size and orientation of a desired final artistic image. The artist prepares the preparatory image by consulting the imprinted digital image 10 as it appears on masking material 40, selecting one or more regions to stylize, and excising those selected regions from the masking material. As in the second embodiment, in this third embodiment the mask that results from excision of the selected regions of masking material 40 is the preparatory image. As in the previous embodiment, the preparatory image is then securely placed on the front surface of metallic sheet 30 as shown in FIG. 3B. The exposed front surface regions 36 of metallic sheet 30 are ready for application of a stylization technique, and those regions not selected for stylization using that technique are masked by masking material 40.

The artist may repeat any number of times the steps of preparing a preparatory image, selecting regions to stylize, placing the preparatory image on the metallic sheet 30, and stylizing the selected regions. Additionally, the order of the claimed method steps concerning i) preparing the preparatory image, ii) selecting one or more regions to stylize, and iii) placing the preparatory image on the metallic sheet may be reordered or performed simultaneously. As described above in the first embodiment, the step of preparing the preparatory image and placing the preparatory image on the metallic sheet may occur simultaneously when light projector 20 projects digital image 10 upon metallic sheet 30. As described in the second and third embodiments, the preparatory image is completed after selecting one or more regions to stylize and excising masking material from the selected regions. The claims encompass performance of these three steps in any order, as well as performance of any or all of the steps concurrently.

After all stylization is completed, the front surface of metallic sheet 30 is thoroughly cleaned before being inserted into a digital printer and imprinted with digital image 10. The cleaning step should remove all or substantially all metal filings, metal dust, chemical residue, oils, and any other extrinsic material. This may be done by using the same sequence of cleaning materials previously described, such as first applying a grease remover such as Professional Strength Goof-Off, followed by Citrasolv, then followed by 70% or greater percentage Isopropyl Alcohol. After the front surface of metallic sheet 30 is cleaned, it is preferable that handlers protect it from any contamination such as dirts or oils, for example by wearing clean latex or cotton gloves to prevent fingerprints.

The cleaned metallic sheet 30 is then placed on its back surface on a substantially flat and level surface to facilitate application of an ink adhesion promotion precoat to its front surface, such as Inkaid Clear Gloss Type II precoat, available from Ontario Specialty Coatings, 22564 Fisher Road, Watertown, N.Y. 13601. This precoat may be applied to the front surface 35 of metallic sheet 30 with a brush, or more preferably by drawing a straight, stiff tool such as a bar or rod across the stylized metal to uniformly cover front surface 35 of metallic sheet 30 with the precoat. Applying light downward pressure on the bar while drawing it across front surface 35 may facilitate penetration of the precoat into the abraded and roughened textures of stylized regions 38. Preferably the placement surface is substantially flat and substantially level. Care must be taken to avoid nonuniform application, overapplication, and or underapplication of the precoat.

The step of applying the precoat may be repeated if it appears that the first application did not provide sufficient coverage. However, multiple applications may promote unwanted puddling of excess precoat, and applying multiple coats of the ink adhesion promotion agent can produce an orange peel effect which may be undesirable.

In one embodiment, metallic sheet 30 is placed on an integral base, such as a large piece of flat plexiglass. However, care must be taken to separate metallic sheet 30 from the plexiglass after the precoat dries. When placed on an integral base, a straight edge utility knife may be used to cut the excess dried precoat away from the precoat adhering to the front surface of metallic base 30. This process can be difficult, necessitating laborious touch-up work to apply more precoat where it may pull away from the metallic sheet.

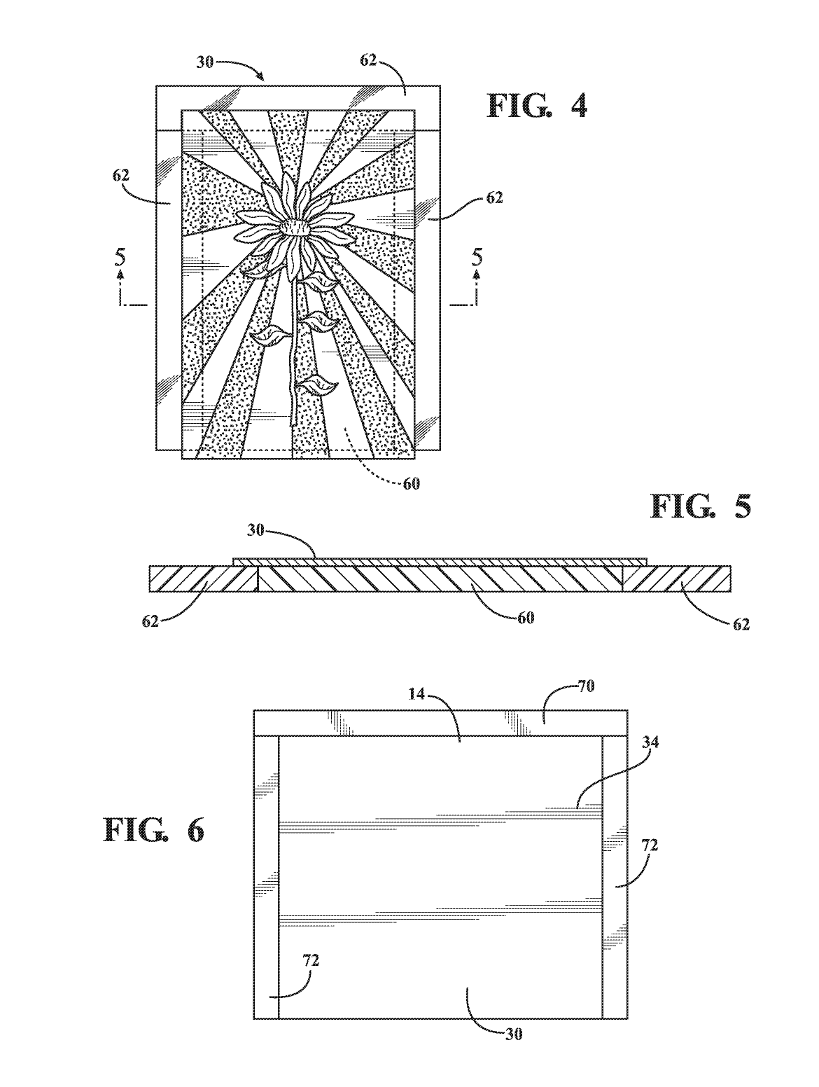

In another embodiment, metallic sheet 30 is placed back side down on a flat level surface comprising a plurality of plexiglass base portions having uniform thickness of about ½ inch to one inch. Referring to FIGS. 4 and 5, metallic sheet 30 is regionally stylized and imprinted with digital image 10 and prepared for application of the precoat. (FIG. 5 dimensions show relative orientation only and are not drawn to scale.) Central base portion 60 underlies the interior regions of metallic sheet 30. Central base portion is preferably smaller in width than the width of metallic sheet 30, and preferably approximately 2-3 inches smaller in width than metallic sheet 30. Abutting central base portion 60 are three side portions 62. The base portions and two parallel side portions have a combined width greater than the width of metallic sheet 30. The remaining side portion situated at a third side of the base and perpendicular to the other side portions extends beneath and 1-2 inches beyond the top edge of metallic sheet 30. One edge of metallic sheet 30 overhangs the edges of abutting base portions 60 and 62.

After the precoat is applied but before it has dried, the three plexiglass side base portions are carefully removed from beneath metallic sheet 30, leaving metallic sheet resting on central base portion 60 with all its edges and nearby back surfaces exposed to air. Removal of the side base portions 62 facilitate drain off of the precoat to minimize precoat puddling on the front surface of metallic sheet 30 and minimize accumulation of excess precoat underneath the back surface of metallic sheet 30.

Following application of the precoat, the precoat is dried. Drying time typically will be 24 hours more or less depending on conditions. Drying time can sometimes be hastened by the use of one or more fans. After the precoat material has dried, the eighth step is to detach the metal from the Plexiglas. Any dried precoat on the back of metallic sheet 30 may be wiped clean with cotton cloth or paper towels. Front surface 35 and front surface edges of metallic sheet 30 are preferably protected from contact with foreign material.

Digital image 10 may now be imprinted on metallic sheet 30 using a digital printer. Preferably an ink jet printer is used, such as the Epson Stylistpro 9900 printer which has a 44-inch print width capacity and is widely available. A custom print profile for metal sheets may be created to optimize printer settings. Such ICC profiles are available through Booksmart Studio, 250 North Goodman Street, Rochester, N.Y. 14607. Printers vary, as do substrate qualities; therefore a custom profile may be desirable to achieve optimum color and depth.

Prior to printing digital image 10, matboard strips 70 and 72 are secured to at least three edges of metallic sheet 30 as shown in FIG. 6. In one embodiment, metallic sheet 30 is oriented so that the sheet edge that is proximate to digital image top 14 abuts a top matboard strip 70, which is substantially parallel to granular direction 34. Side matboard strips 72 abut the sides of metallic sheet 30. Side matboard strips 72 and are sized such that their width when combined with the width of metallic sheet 30 equals the width capacity of the digital printer, e.g., 44 inches for the Epson Sylistpro 9900. The top matboard strip 70 and two parallel side matboard strips 72 are all secured to the back surface of metallic sheet 30 with suitable tape. It will be appreciated that in some embodiments digital image top 14 could abut one of side matboard strips 72; in that case, granular direction 14 would be substantially parallel to side matboard strips 72.

The matboard strips facilitate accurate guidance of metallic sheet 30 during the printing step, which may last many minutes. Top matboard strip 70 is inserted first into the printer. Metallic sheet 30 can be fed into the printer by hand using one or preferably two people if the sheet is large or heavy. Various guides such as C-clamps may be attached to the printer's feed system and/or output section to assist with proper placement and alignment of metallic sheet 30 during printing. Rollers or a roller-table may also be used to support the sheet during loading into the printer. Despite such guides and tables, it may still be preferable to manipulate the loading and printing of the stylized metal by hand in order to achieve and maintain desired margins. Rollers, roller-tables and discharge guides may also be used as the sheet discharges from the printer, or the sheet may be supported by hand.

As discussed earlier, a horizontal orientation of granular direction 34 has a significant positive impact on the final displayed artpiece when combined with the printing and stylization and treatment methods described herein and when the finished artpiece is illuminated by a directed light source or plurality of light sources directed at the displayed artpiece from above. The light source(s) may be comprised of a single color (such as broad spectrum white) or multiple colors (such as one or more multi-color LEDs). The finished piece has inherent reflectivity, which a glossy clear coat can accentuate. When a light source is directed at the displayed artpiece from above, reflected light beams tend to travel along the same direction as granular direction 34. When granular direction 34 is horizontal in the displayed regionally stylized artpiece, an observer perceives most of the light source beams being cast horizontally off the front surface 35; horizontally casted light source beams may enhance desired luminosity and desired 3-D effect for an observer. In contrast, when an above-mounted light source is directed at a regionally stylized artpiece having a vertical granular direction 34, an observer perceives light source beams cast up and down, resulting in undesirable vertical light source bands, lines, and/or “hot spots” of reflected lighting and potentially interfering with the desired 3-D effect.

After the digital image 10 is imprinted on the regionally stylized metallic sheet 30, a postcoat may be applied to the metallic sheet to preserve and protect the ink. One product that may be used is a car finish urethane, SelectClear 2K 498-00 Multi-Panel & Overall Clearcoat. This may be mixed with 483-78 Mid Temp Activator in accordance with directions listed on the SelectClear 2K can. Preferably two coats are applied, with approximately 3-5 minutes drying time between coats, and may include a glossy clear coat. The clear coat may be applied in any number of known techniques, but is preferably applied using an air gun sprayer. The post-coated regionally stylized metallic sheet 30 is then cured. Curing time is preferably 12-24 hours at approximately 70 degrees Fahrenheit.

After the post coat has dried, the artpiece may be finished using techniques such as wet-sanding, buffing with rubbing compound, and polishing according to practices well known in the art.

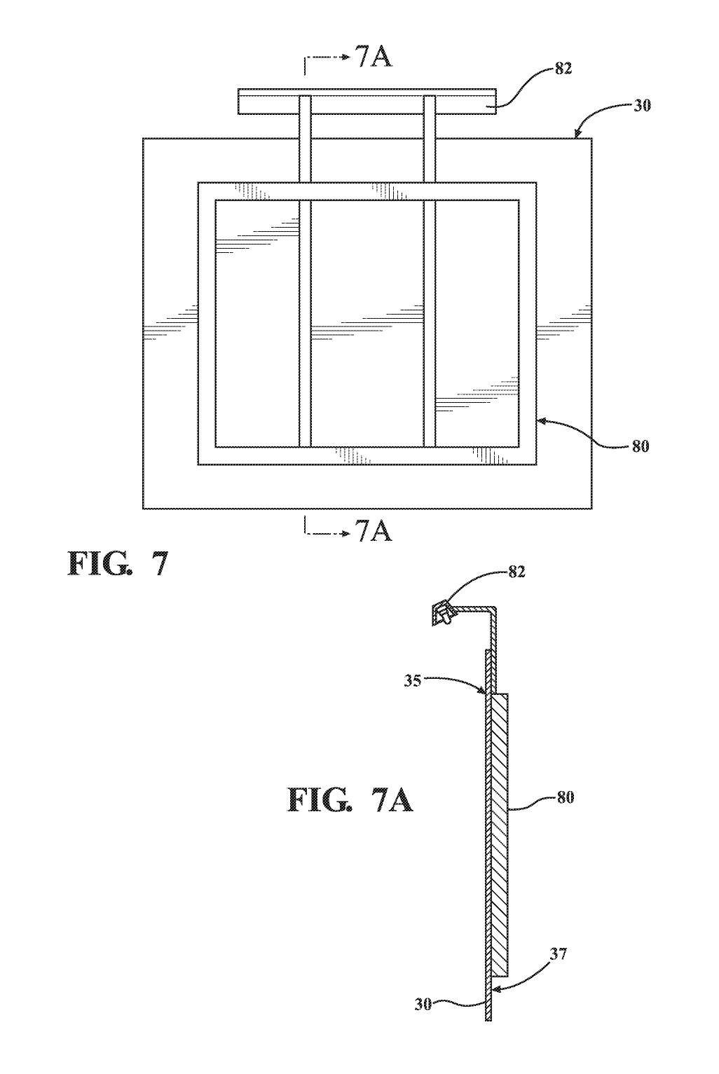

An inner back frame may be fabricated if a traditional outer front frame is not being used and when not using built in custom lighting. Referring to FIGS. 7 and 7A, an inner frame 80 is welded using a TIG welder and aluminum U channel, and is fabricated with a perimeter sized to be several inches smaller than the perimeter of the stylized/printed metallic sheet 30. The dimensions and desired position of the inner back frame are traced onto the back of metallic sheet 30. Metallic sheet 30 is secured to a sturdy foam core board surface with electrical tape and the tracings grinded and cleaned, and the corresponding contact surfaces of inner frame 80 are abraded and cleaned using cleaners described above. After printing, an adhesive such as 3M Marine Adhesive Sealant 5200 White Prior is applied to inner frame 80 and the mating regions on the back surface of the metallic sheet. The inner frame is then aligned with the positions previously traced on the back of metallic sheet 30 and adhered to it.

As shown in FIGS. 7 and 7A, lighting array 82 directing light to front surface 35 of metallic sheet 30 may be attached to inner frame 80, said lighting array 82 preferably comprising a plurality of LED lights. Optionally, the frame may house electronics (not shown) to operate lighting array 82. The electronics may be programmed to cycle lighting having varying colors, intensities, and/or at varying cycle frequencies, for example using programable LED tape. The electronics program may be stored in read-only-memory or may be controlled by a user using well-known equipment such as a DMX LED controller. Lighting effects can be customized particularly for that art piece and for the owner's desired lighting effects in order to achieve optimal and/or dynamic lighting effects in conjunction with the regional stylization and granular direction 34.

Applicants' invention is a unique and entirely original method of printing onto metal. The invention allows an artist to produce a printed image that exhibits exceptional luminosity, that uniquely accentuates aspects of a digital image, and that promotes greater interactivity between the artpiece and the observer as he views the artpiece from various viewing angles. The interaction between light, the observer, and the artpiece produced by the disclosed method mimics three-dimensional qualities which can be further amplified with custom lighting. The final artpiece when properly finished may be displayed in environments where other image substrates may not be appropriate, such as near water, out of doors, or in areas exposed to ultraviolet light.

The foregoing invention has been described in accordance with the relevant legal standards, thus the description is exemplary rather than limiting in nature. Variations and modifications to the disclosed embodiment may become apparent to those skilled in the art and fall within the scope of the invention.

What is claimed is:

1. A method of printing a digital image on a metallic sheet having a front surface, said method comprising the steps of:
preparing a preparatory image having dimensions corresponding to the dimensions desired for the printed image;
selecting one or more first regions of the front surface for stylization;
placing the preparatory image on the front surface of the metallic sheet;
stylizing the selected first regions according to a first technique; and then
digitally printing the digital image upon the regionally stylized front surface of the metallic sheet to produce the artistic image.

2. The method of claim 1 wherein the preparatory image comprises a light projection of the digital image projected by a light projector.

3. The method of claim 1 wherein the preparatory image comprises a masking material.

4. The method of claim 3 wherein the masking material comprises an imprint of the digital image.

5. The method of claim 3 further comprising the step, prior to stylizing the selected first regions, of projecting the digital image upon the masking material using a light projector.

6. The method of claim 3 further comprising the step, prior to placing the preparatory image on the front surface of the metallic sheet, of excising portions of the masking material corresponding to the selected first regions and leaving the remainder of the masking material as part of the preparatory image.

7. The method of claim 1 further comprising the step, subsequent to selecting one or more first regions for stylization, of withholding stylization according to the first technique from one or more unselected regions of the front surface.

8. The method of claim 1 wherein the first technique is selected from the group consisting of physical abrasion, chemical treatment, and application of heat;

9. The method of claim 1 wherein the imprinted digital image has a top and the metallic sheet has a granular direction that is substantially horizontal relative to the top of the imprinted digital image.

10. The method of claim 1 further comprising the step, prior to digitally printing, of:
selecting one or more second regions of the front surface for stylization;
stylizing the selected second regions according to a second technique.

11. The method of claim 1 further comprising the step, prior to digitally printing, of removing substantially all material extrinsic to the metallic sheet.

12. The method of claim 11 further comprising the step, subsequent to removing substantially all material extrinsic to the metallic sheet, of applying to the front surface an ink adhesion precoat.

13. The method of claim 12 further comprising the steps, subsequent to removing substantially all material extrinsic to the metallic sheet and prior to printing, of:
placing a back surface of the metallic sheet on a substantially flat and level surface with the front surface exposed and facing upwards;
providing a dispersion tool;
applying the ink adhesion precoat to the front surface; and
drawing the dispersion tool horizontally across the front surface to distribute the precoat across substantially all of the front surface.

14. The method of claim 13 wherein the substantially flat and level surface comprises a plurality of base portions.

15. The method of claim 14 wherein the plurality of base portions comprises a central portion, a first side portion abutting the central portion, a second side portion abutting the central portion, and a third side portion abutting the central portion, and wherein the area of the metallic sheet is larger than the area of the central portion and is smaller than the combined area of the plurality of base portions.

16. The method of claim 15 further comprising the step subsequent to drawing the rod horizontally across the front surface to uniformly distribute the precoat, of removing one or more side portions from underneath the metallic sheet to expose one or more edges and nearby back surfaces of the metallic sheet.

17. An artpiece produced by the process of claim 1 wherein a front surface of a metallic sheet comprising a plurality of regions having varying surface textures is imprinted with an image by a digital printer.

18. The artpiece of claim 17 further comprising a substantially rectangular metal frame adhered to a back surface of the metallic sheet.

19. The artpiece of claim 17 further comprising a programmable LED lighting array directed at the front surface.

20. A method of printing a digital image on an aluminum sheet, the digital image having a top and the aluminum sheet having a front surface, a back surface, and a granular direction, comprising the steps of:
projecting the digital image upon a sheet of masking material using a light projector;
sizing the projected digital image to correspond to the dimensions of a desired artistic image;
selecting one or more first regions of the projected image for stylization according to a first technique;
producing a preparatory image by excising portions of the masking material corresponding to the selected first regions and leaving the remainder of the masking material;
adhering the preparatory image to the front surface of the aluminum sheet;
stylizing the excised areas of the preparatory image according to a first technique selected from the group consisting of physical abrasion, chemical treatment, and application of heat;
removing the preparatory image from the front surface;
removing substantially all material extrinsic to the aluminum sheet;
placing the aluminum sheet with the front surface exposed and facing upwards on a substantially flat and level surface, said surface comprising a central portion, a first side portion abutting the central portion, a second side portion abutting the central portion, and a third side portion abutting the central portion, wherein the aluminum sheet is larger than the area of the central portion and smaller than the combined area of the central and side portions;
applying an ink adhesion precoat to the front surface using a metering rod to distribute the precoat across substantially all of the front surface;
removing one or more of the side portions from underneath the aluminum sheet to expose one or more edges and nearby back surfaces of the aluminum sheet to air;
drying the precoat; and
digitally printing the digital image upon the regionally stylized front surface of the aluminum sheet such that the granular direction is substantially horizontal relative to the top of the imprinted digital image; and
applying at least one protective postcoat to the front surface.
